(19) United States
(12) Patent Application Publication
(10) Pub. No.: US 2025/0010340 A1
(43) Pub. Date: Jan. 9, 2025

(54) RESIDUE SCRAPER

(71) Applicant: TCL ZHONGHUAN RENEWABLE ENERGY TECHNOLOGY CO., LTD., Tianjin (CN)

(72) Inventors: Yilin XU, Tianjin (CN); Rui WU, Tianjin (CN); Zhijun WU, Tianjin (CN); Zhengmin CAO, Tianjin (CN); Ruipeng LI, Tianjin (CN); Dawei WANG, Tianjin (CN); Yao WAN, Tianjin (CN)

(73) Assignee: TCL ZHONGHUAN RENEWABLE ENERGY TECHNOLOGY CO., LTD., Tianjin (CN)

(21) Appl. No.: 18/548,099

(22) PCT Filed: Jul. 31, 2023
(86) PCT No.: PCT/CN2023/110388

§ 371 Date: Aug. 27, 2023

(30) Foreign Application Priority Data
Aug. 29, 2022 (CN) 202222273881.7

(51) Int. Cl. B08B 1/16; B08B 1/30; B08B 13/00; H01L 21/02

(52) U.S. Cl. CPC B08B 1/165; B08B 1/30; B08B 13/00; H01L 21/02046

(57) ABSTRACT

A residue scraper is provided, which includes a machine frame, which is provided with a clamping unit for fastening a material holder; a scraper unit for cleaning residues on a to-be-cleaned surface of the material holder, and a driving unit that drives the scraper unit to reciprocate along a long side direction of the material holder. In the present invention, the scraper unit is driven by the driving unit to scrape off the residues, thereby achieving a high efficiency to remove the residues.

### CROSS-REFERENCE TO RELATED APPLICATION

The present disclosure claims priority to China Patent Application No. 202222273881.7, filed on Aug. 29, 2022, which is incorporated herein by reference in its entirety.

### TECHNICAL FIELD

The present disclosure relates to silicon chip production, and more particularly, to a residue scraper.

### BACKGROUND

In recent years, the output of monocrystalline silicon in China has grown steadily and obviously. The reason for the increase is that on the one hand, an increasing demand on low-grade and cheap silicon materials spreads internationally. On the other hand, China's equipment manufacturing has developed rapidly in these years, and the demand on various information appliances and communication products is strong. Therefore, the market needs a large amount of semiconductor devices and silicon materials.

In the silicon wafer production process, it is necessary to stick monocrystalline silicon ingot to a resin plate of a material holder for wire cutting. The material holder and the resin plate are bonded by glue. After wire cutting, silicon wafers are peeled off, and residues, such as waste monocrystalline wafers, waste resin strips, etc., will be left on the resin plate. When the residues are transferred to the production return line, it needs to clean the residues on the resin plate, in order to prevent the residues from piling up on the material holder and ensure successful grabbing of a manipulator for sticky plates.

### SUMMARY

The present disclosure is to provide a residue scraper.

The innovation is that a scraper unit is driven by a driving unit to scrape off the residues, thereby achieving a high efficiency to remove the residues.

For achieving the objective of the present disclosure, the technical solutions provided in the present disclosure are:

A residue scraper, including a machine frame, which is provided with a clamping unit for fastening a material holder; a scraper unit for cleaning residues on a to-be-cleaned surface of the material holder; and a driving unit that drives the scraper unit to reciprocate along a long side direction of the material holder.

The clamping unit fixes the material holder, the driving unit drives the movement of the scraper unit, and the scraper unit scrapes off the residues on the material holder. In such a way, the residues peel off automatically, and the residues are removed efficiently.

Optionally, the machine frame is a rectangular frame and is covered by a cover to protect the scraper unit, the driving unit and the clamping unit, a residue bucket is provided under the machine frame, and the machine frame includes two long sides arranged in parallel and two short sides arranged in parallel. Since the material holder is a cuboid structure, the rectangular frame can effectively reduce the occupied space of the equipment.

Optionally, the scraper unit includes two skid rails arranged on the two long sides respectively, pneumatic slide tables arranged on the skid rails, and a scraper located in parallel with the short sides and arranged between two pneumatic slide tables, and the scraper includes a scraper connector connecting to the two pneumatic slide tables and blades arranged on the scraper connector and located in parallel with two later faces of the short sides. The skid rails and the pneumatic slide tables limit the moving direction of the scraper unit, and there are blades on both sides of the scraper. In such a way, reciprocation of the scraper is realized to scrape the residues.

Optionally, the driving unit includes two rotating shafts arranged parallel with the short sides, the rotating shafts mount on two ends of the long sides via bearing pedestals, sprockets are arranged at two ends of the rotating shafts, and ring-shaped chains are used to connect the sprockets, the scraper unit is fastened to the ring-shaped chains, a motor is suspended on one of the rotating shafts, and the frame is provided with a motor overload protection unit. The motor drives the shafts, the shafts drive the sprockets to rotate, the sprockets drive the chains to rotate, and the chains drive the scraper unit to move. In such a way, the structure is simple, the degree of automation is high, and it is easy for maintenance.

Optionally, the clamping unit includes clamping cylinders arranged on two long sides and one short side of the frame, and a position limiting plate arranged on the other short side, pistons of the clamping cylinders face the inside of the frame, and the pistons of the clamping cylinders are connected to L-shaped splints for snapping into the material holder. The clamping cylinders are used for clamping. The clamping cylinders respond quickly, have a high degree of automation and are easy to maintain.

Optionally, the clamping cylinders on the long sides are connected to the frame via L-shaped supports, and the L-shaped supports includes horizontal plates on which the clamping cylinder are placed, and vertical plates connecting to the frame. The L-shaped supports are used to make way for the driving unit.

Optionally, the motor overload protection unit includes a rotating plate fastened to the motor and a trigger plate fastened to the frame, the rotating plate is arranged perpendicular to the rotating shafts, the trigger plate is provided with a vertically-arranged rod, position limiting blocks are arranged at both ends of the rod, a connecting block is provided on the rotating plate, the connecting block is located between two position limiting blocks, the connecting block is provided with a through hole for the rod to pass through, springs sleeved on the rod are arranged between the position limiting blocks and the connecting block, the trigger plate is provided with two micro switches, the rotating plate is provided with a check disc for triggering the micro switches, and the micro switches are electrically connected to the motor. When motor overload reaches a preset threshold, the motor will rotate around the rotating shaft, the spring will be compressed, the check disc will contact the micro switches, and the motor will stop. When the motor shakes slightly, the springs can absorb the vibration and return the motor to its original position, and the check disc will not contact the micro switches all the while.

Optionally, one of the long sides is provided with two proximity switches, the proximity switches are located at two margin positions respectively, where the scraper unit reaches, and the proximity switches are electrically connected to the motor. The margin positions of the scraper unit are controlled by the proximity switches.

The beneficial effects of the present disclosure are:

1. In the present disclosure, the scraper unit is driven by the driving unit to scrape off the residues, thereby achieving a high efficiency to remove the residues.

2. In the present disclosure, the motor is protected by the motor overload protection unit so as to avoid overloading of the motor, caused by excessive resistance suffered by the scraper unit.

3. In the present disclosure, the margin positions of the scraper unit are controlled by the proximity switches.

### BRIEF DESCRIPTION OF THE DRAWINGS

FIG. 1 is an exploded view of a residue scraper according to the present disclosure.

FIG. 2 is a schematic diagram illustrating the internal structure of a residue scraper.

FIG. 3 is a schematic structural diagram of a scraper unit and a driving unit.

FIG. 4 is a schematic structural diagram of a machine frame.

FIG. 5 is a schematic structural diagram of a motor overload protection unit.

LIST OF REFERENCE SIGNS

| | | |
|---|---|---|
| 1: Machine frame; | 1.1: Long side; | 1.2: Short side |
| 2: Clamping unit; | | |
| 2.1: Clamping cylinder; | 2.2: Position limiting plate; | 2.3: L-shaped splint; |
| 2.4: L-shaped support; | | |
| 2.41: Horizontal plate; | 2.42: Vertical plate; | |
| 3: Scraper unit; | | |
| 3.1: Skid rail; | 3.2: Pneumatic slide table; | 3.3: Scraper |
| 3.31: Scraper connector | 3.32: Blade; | |
| 4: Driving unit | | |
| 4.1: Rotating shaft; | 4.2: Sprockets; | 4.3: Ring-shaped chains; |
| 4.4: Motor; | 4.5: Protection unit; | 4.6: Proximity switch; |
| 4.7: Bearing pedestal; | | |
| 4.51: Rotating plate; | 4.52: Trigger plate; | 4.53: Rod; |
| 4.54: Position limiting block; | 4.55: Connecting block; | 4.551: Through hole; |
| 4.56: Spring; | 4.57: Micro switch | 4.58: Check disc; |
| 5: Cover; | 6: Residue bucket. | |

### DETAILED DESCRIPTION

The technical solutions in the embodiments of the present disclosure will be clearly and completely described below with reference to the accompanying drawings.

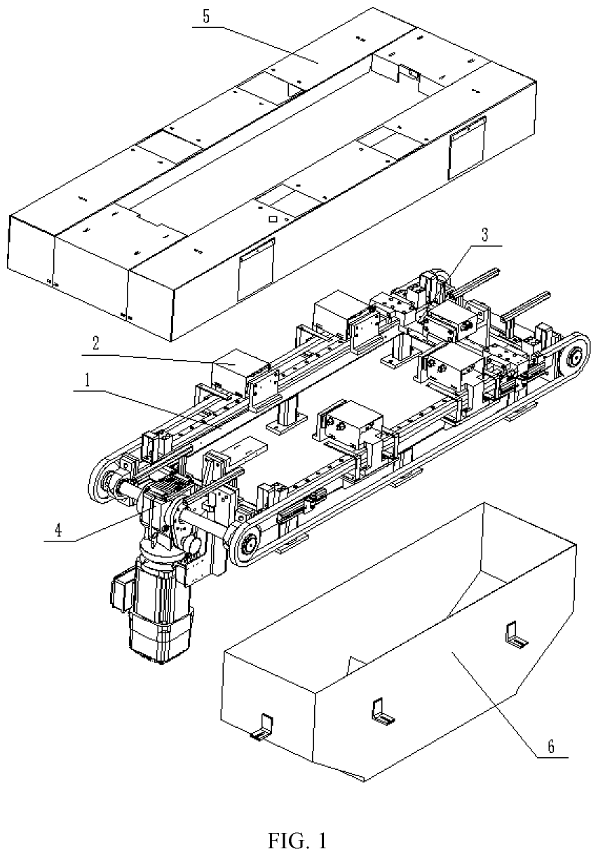

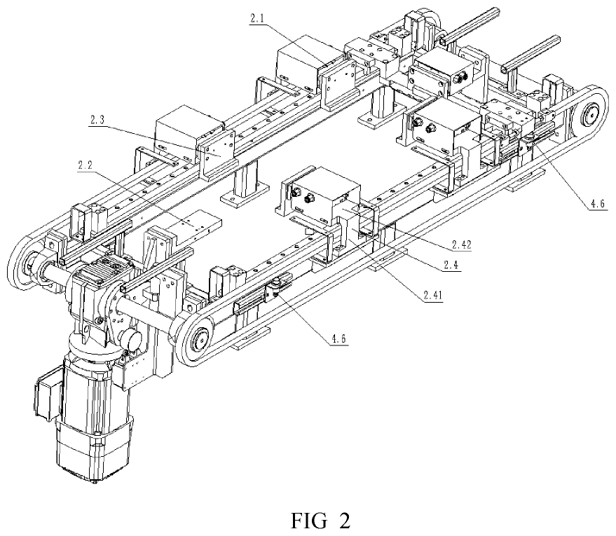

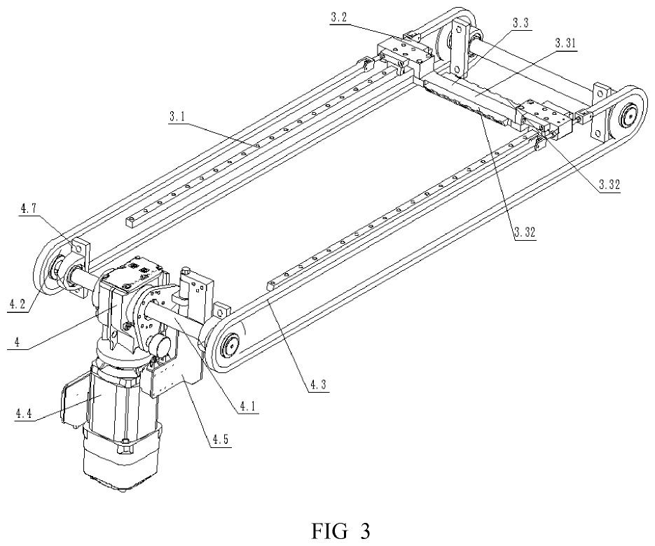

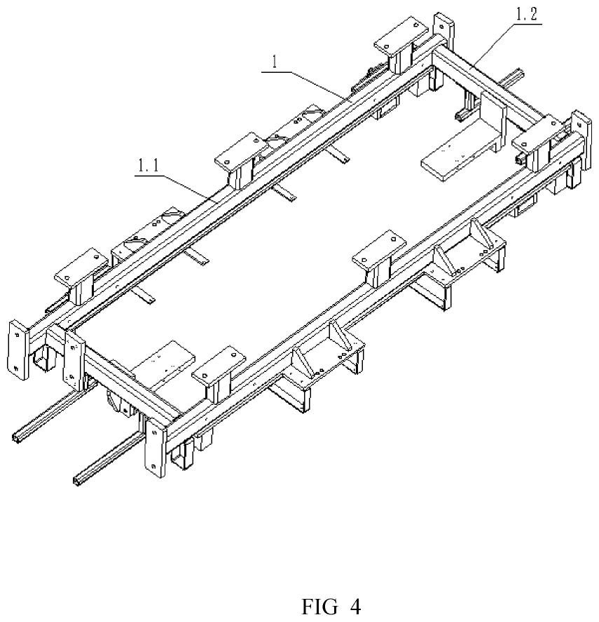

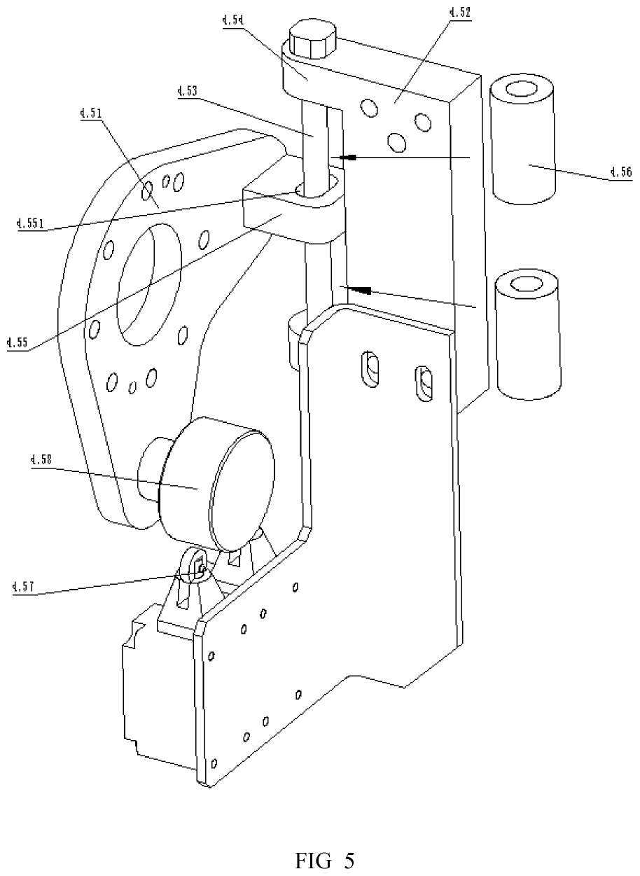

Embodiment 1: As shown in FIGS. 1 to 5, a residue scraper includes a machine frame 1, which is provided with a clamping unit 2 for fastening a material holder, a scraper unit 3 for cleaning the residues on a to-be-cleaned surface of the material holder, and a driving unit 4 that drives the scraper unit 3 to reciprocate along a long side direction of the material holder. The machine frame 1 is a rectangular frame and is covered by a cover 5 to protect the scraper unit 3, the driving unit 4 and the clamping unit 2. A residue bucket 6 is provided under the machine frame 1. The machine frame 1 includes two long sides 1.1 arranged in parallel and two short sides 1.2 arranged in parallel. The scraper unit 3 includes two skid rails 3.1 arranged on the two long sides 1.1 respectively, pneumatic slide tables 3.2 arranged on the skid rails 3.1, and a scraper 3.3 located in parallel with the short sides 1.2 and arranged between two pneumatic slide tables 3.2. The scraper 3.3 includes a scraper connector 3.31 connecting to the two pneumatic slide tables 3.2 and a blade 3.32 arranged on the scraper connector 3.31 and located in parallel with two later faces of the short sides. The driving unit 4 includes two rotating shafts 4.1 arranged parallel with the short sides 1.2. The rotating shafts 4.1 mount on two ends of the long sides 1.1 via bearing pedestals 4.7. Sprockets 4.2 are arranged at two ends of the rotating shafts 4.1, and ring-shaped chains 4.3 are used to connect the sprockets 4.2. The scraper unit 3 is fastened to the ring-shaped chains 4.3. A motor 4.4 is suspended on one of the rotating shafts 4.1. The frame 1 is provided with a motor overload protection unit 4.5. The motor overload protection unit 4.5 includes a rotating plate 4.51 fastened to the motor 4.4 and a trigger plate 4.52 fastened to the frame 1. The rotating plate 4.51 is arranged perpendicular to the rotating shafts 4.1. The trigger plate 4.52 is provided with a vertically-arranged rod 4.53. Position limiting blocks 4.54 are arranged at both ends of the rod 4.53. A connecting block 4.55 is provided on the rotating plate 4.51. The connecting block 4.55 is located between two position limiting blocks 4.54. The connecting block 4.55 is provided with a through hole 4.551 for the rod 4.53 to pass through. Springs 4.56 sleeved on the rod 4.53 are arranged between the position limiting blocks 4.54 and the connecting block 4.55. The trigger plate 4.52 is provided with two micro switches 4.57, and the rotating plate 4.51 is provided with a check disc 4.58 for triggering the micro switches 4.57. The micro switches 4.57 are electrically connected to the motor 4.4. One of the long sides 1.1 is provided with two proximity switches 4.6. The proximity switches 4.6 are located at two margin positions respectively, where the scraper unit 3 reaches. The proximity switches 4.6 are electrically connected to the motor 4.4. The clamping unit 2 includes clamping cylinders 2.1 arranged on two long sides 1.1 and one short side 1.2 of the frame, and a position limiting plate 2.2 arranged on the other short side 1.2. Pistons of the clamping cylinders 2.1 face the inside of the frame 1. The pistons of the clamping cylinders 2.1 are connected to L-shaped splints 2.3 for snapping into the material holder. The clamping cylinders 2.1 on the long sides are connected to the frame 1 via L-shaped supports 2.4. The L-shaped supports 2.4 includes horizontal plates 2.41 on which the clamping cylinder 2.1 are placed, and vertical plates 2.42 connecting to the frame 1.

Operations are described below. A manipulator in the workshop grips the material holder, keeps the to-be-cleaned surface of the material holder facing down and places it in the center of the frame 1. The clamping cylinders 2.1 are then used to clamp the material holder. The motor 4.4 rotates and drives the rotating shafts 4.1 to rotate. The rotating shafts 4.1 drive the sprockets 4.2 to rotate. The sprockets 4.2 drive the chains 4.1 to rotate. The chains 4.1 drive the scraper connector 3.31 to move along the skid rails 3.1. The blade 3.32 scrapes the to-be-cleaned surface of the material holder. When the pneumatic slide tables 3.2 on the scraper unit 3 moves and stops at the margin positions, the proximity switch 4.6 detects the scraper unit 3. Then, the motor 4.4 reverses, and the other blade 3.32 scrapes the to-be-cleaned surface of the material holder again. When the pneumatic slide tables 3.2 returns to the initial position, the proximity switch 4.4 at the other end triggers the motor 4.4 to stop rotating. The manipulator clamps the material holder, and the clamping cylinders 2.1 release it. When the resistance the scraper unit 3 scrapes off the residues is too large, the motor 4.4 will rotate around the rotating shafts 4.1. When the torque generated by the motor 4.4 is greater than the deflection of the springs 4.56 such that the check disc 4.58 on the rotating plate 4.51 touches the micro switches 4.57, the micro switches 4.57 transmit electric signals to the motor 4.4 to stop the motor 4.4.

The described embodiments are merely a part of embodiments and are not all of the embodiments of the present disclosure. Based on the embodiments of the present disclosure, all the other embodiments obtained by those of ordinary skill in the art without making any inventive efforts are within the scope sought to be protected in the present disclosure.

What is claimed is:

1. A residue scraper, comprising a machine frame, which is provided with a clamping unit for fastening a material holder; a scraper unit for cleaning residues on a to-be-cleaned surface of the material holder; and a driving unit that drives the scraper unit to reciprocate along a long side direction of the material holder.

2. The residue scraper of claim 1, wherein the machine frame is a rectangular frame and is covered by a cover to protect the scraper unit, the driving unit and the clamping unit, a residue bucket is provided under the machine frame, and the machine frame includes two long sides arranged in parallel and two short sides arranged in parallel.

3. The residue scraper of claim 2, wherein the scraper unit includes two skid rails arranged on the two long sides respectively, pneumatic slide tables arranged on the skid rails, and a scraper located in parallel with the short sides and arranged between two pneumatic slide tables, and the scraper includes a scraper connector connecting to the two pneumatic slide tables and blades arranged on the scraper connector and located in parallel with two later faces of the short sides.

4. The residue scraper of claim 2, wherein the driving unit includes two rotating shafts arranged parallel with the short sides, the rotating shafts mount on two ends of the long sides via bearing pedestals, sprockets are arranged at two ends of the rotating shafts, and ring-shaped chains are used to connect the sprockets, the scraper unit is fastened to the ring-shaped chains, a motor is suspended on one of the rotating shafts, and the frame is provided with a motor overload protection unit.

5. The residue scraper of claim 2, wherein the clamping unit includes clamping cylinders arranged on two long sides and one short side of the frame, and a position limiting plate arranged on the other short side, pistons of the clamping cylinders face the inside of the frame, and the pistons of the clamping cylinders are connected to L-shaped splints for snapping into the material holder.

6. The residue scraper of claim 5, wherein the clamping cylinders on the long sides are connected to the frame via L-shaped supports, and the L-shaped supports includes horizontal plates on which the clamping cylinder are placed, and vertical plates connecting to the frame.

7. The residue scraper of claim 4, wherein the motor overload protection unit includes a rotating plate fastened to the motor and a trigger plate fastened to the frame, the rotating plate is arranged perpendicular to the rotating shafts, the trigger plate is provided with a vertically-arranged rod, position limiting blocks are arranged at both ends of the rod, a connecting block is provided on the rotating plate, the connecting block is located between two position limiting blocks, the connecting block is provided with a through hole for the rod to pass through, springs sleeved on the rod are arranged between the position limiting blocks and the connecting block, the trigger plate is provided with two micro switches, the rotating plate is provided with a check disc for triggering the micro switches, and the micro switches are electrically connected to the motor.

8. The residue scraper of claim 4, wherein one of the long sides is provided with two proximity switches, the proximity switches are located at two margin positions respectively, where the scraper unit reaches, and the proximity switches are electrically connected to the motor.

9. A residue scraper, comprising a machine frame, which is provided with a clamping unit for fastening a material holder; a scraper unit for cleaning residues on a to-be-cleaned surface of the material holder; and a driving unit that drives the scraper unit to reciprocate along a long side direction of the material holder,
wherein the machine frame includes two long sides arranged in parallel and two short sides arranged in parallel, the driving unit includes two rotating shafts arranged parallel with the short sides, the rotating shafts mount on two ends of the long sides via bearing pedestals, sprockets are arranged at two ends of the rotating shafts, and ring-shaped chains are used to connect the sprockets, the scraper unit is fastened to the ring-shaped chains, a motor is suspended on one of the rotating shafts, and the frame is provided with a motor overload protection unit.

10. The residue scraper of claim 9, wherein the motor overload protection unit includes a rotating plate fastened to the motor and a trigger plate fastened to the frame, the rotating plate is arranged perpendicular to the rotating shafts, the trigger plate is provided with a vertically-arranged rod, position limiting blocks are arranged at both ends of the rod, a connecting block is provided on the rotating plate, the connecting block is located between two position limiting blocks, the connecting block is provided with a through hole for the rod to pass through, and springs sleeved on the rod are arranged between the position limiting blocks and the connecting block.

11. The residue scraper of claim 10, wherein the trigger plate is provided with two micro switches, the rotating plate is provided with a check disc for triggering the micro switches, and the micro switches are electrically connected to the motor.

12. The residue scraper of claim 9, wherein one of the long sides is provided with two proximity switches, the proximity switches are located at two margin positions respectively, where the scraper unit reaches, and the proximity switches are electrically connected to the motor.

13. The residue scraper of claim 9, wherein the scraper unit includes two skid rails arranged on the two long sides respectively, pneumatic slide tables arranged on the skid rails, and a scraper located in parallel with the short sides and arranged between two pneumatic slide tables.

14. The residue scraper of claim 13, wherein the scraper includes a scraper connector connecting to the two pneumatic slide tables and blades arranged on the scraper connector and located in parallel with two later faces of the short sides.

15. The residue scraper of claim 9, wherein the clamping unit includes clamping cylinders arranged on two long sides and one short side of the frame, and a position limiting plate arranged on the other short side.

16. The residue scraper of claim 15, wherein pistons of the clamping cylinders face the inside of the frame, and the pistons of the clamping cylinders are connected to L-shaped splints for snapping into the material holder.

17. The residue scraper of claim 16, wherein the clamping cylinders on the long sides are connected to the frame via L-shaped supports.

18. The residue scraper of claim 17, wherein the L-shaped supports includes horizontal plates on which the clamping cylinder are placed, and vertical plates connecting to the frame.
